(19) United States
(12) Patent Application Publication
(10) Pub. No.: US 2026/0304679 A1
(43) Pub. Date: Oct. 1, 2026

(54) INFORMATION HANDLING SYSTEM WITH COMPREHENSIVE LEAK DETECTION MESSAGING

(71) Applicant: DELL PRODUCTS L.P., Round Rock, TX (US)

(72) Inventors: Amrita Sidhu Maguire, Cedar Park, TX (US); Richard Boyle, Boston, MA (US); Michael Stumpf, Cedar Park, TX (US); Toby Schaeffer, Watertown, MA (US); Eduardo Escamilla, Round Rock, TX (US); Ashwini Paradkar, Austin, TX (US)

(21) Appl. No.: 19/096,134

(22) Filed: Mar. 31, 2025

(51) Int. Cl. H05K 7/14; H05B 45/00; H05B 47/105

(52) U.S. Cl. CPC H05K 7/1495; H05B 45/00; H05B 47/105; H05K 7/1494

(57) ABSTRACT

A server rack includes an information handling system and a top of rack leak indicator. The information handling system includes a leak detection component and a leak light emitting diode (LED). The leak detection component monitors the information handling system for a coolant leak. In response to a detection of the coolant leak, the leak detection component provides a leak indication. The leak LED is located on a front panel of the information handling system and is activated in response to the leak indication. In response to the leak indication, the top of rack leak indicator provides focused and clear messaging about the detection of the coolant leak in the server rack.

### FIELD OF THE DISCLOSURE

The present disclosure generally relates to information handling systems, and more particularly relates to an information handling system with comprehensive leak detection messaging.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A server rack includes an information handling system and a top of rack leak indicator. The information handling system includes a leak detection component and a leak light emitting diode (LED). The leak detection component may monitor the information handling system for a coolant leak. In response to a detection of the coolant leak, the leak detection component may provide a leak indication. The leak LED located on a front panel of the information handling system and may be activated in response to the leak indication. In response to the leak indication, the top of rack leak indicator may provide focused and clear messaging about the detection of the coolant leak in the server rack.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of a server rack including multiple information handling systems according to at least one embodiment of the present disclosure;

FIG. 2 is a diagram of a top of rack display according to at least one embodiment of the present disclosure;

FIGS. 3 and 4 are diagrams of graphical user interfaces on a console associated with an information handling system according to at least one embodiment of the present disclosure;

FIG. 5 is a flow diagram of a method for providing comprehensive leak detection messaging according to at least one embodiment of the present disclosure; and

FIG. 6 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

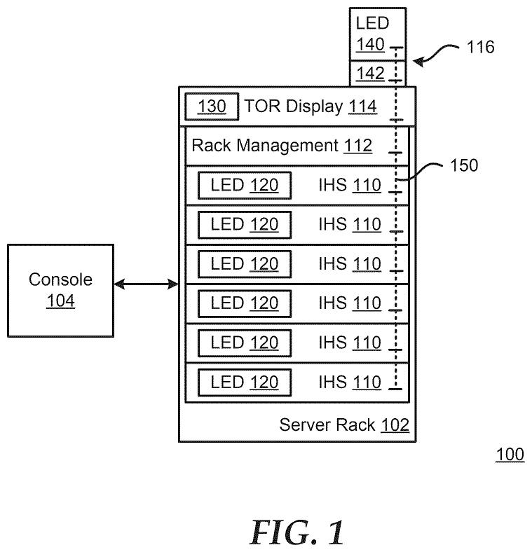

FIG. 1 illustrates a system 100 including a server rack 102 and a console 104 according to at least one embodiment of the present disclosure. Server rack 102 includes multiple information handling systems 110. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

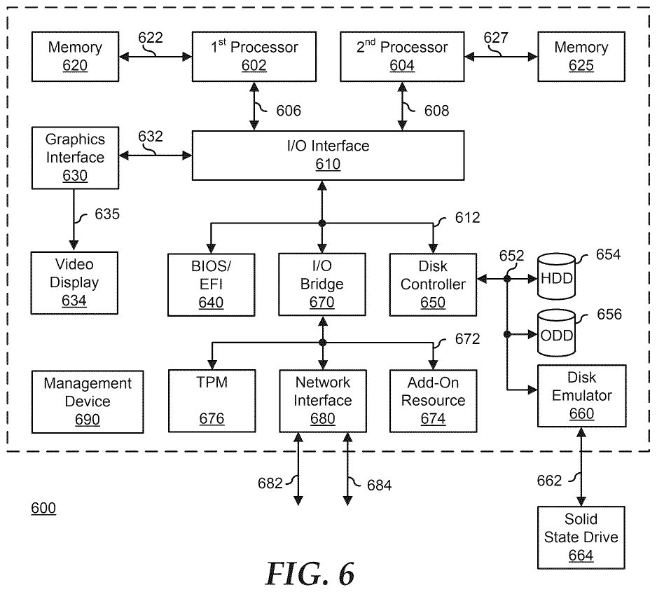

Sever rack 102 also includes a rack management component 112, a top of rack (TOR) display 114, and a TOR leak indicator 116. Each information handling system 110 includes a light emitting diode (LED) 120. TOR display 114 may provide a leak detection icon 130 as will be described herein. TOR leak indicator 116 includes a visual leak indicator 140 and an audio leak indicator 142. Information handling system 110, rack management component 112, TOR display 114, and TOR leak indicator 116 may communicate through any suitable type of connection, such as a communication path 150. In an example, communication path 150 may be an electrical bus, such as leak sense device chain, a liquid-proof optical bus, or the like. Information handling systems 110 may include additional components, such as the components of information handling system 600 in FIG. 6, without varying from the scope of this disclosure. System 100 may include additional components without varying from the scope of this disclosure.

In an example, one or more of information handling systems 110 may execute artificial intelligence (AI)/machine learning (ML) operations within the components of the respective information handling system. The execution of AI/ML operations may produce a large amount of heat within information handling systems 110. As such, information handling systems 110 may include direct liquid cooling (DLC) solutions to manage the thermal/power loads that AI/ML operations create.

In certain examples, a coolant leak within the DLC may create a failure mode in the corresponding information handling system 110. When a coolant leak occurs, the leak should be addressed promptly to prevent costly damage and down time for the corresponding information handling system 110. In an example, each information handling system 110 with DLC may include any suitable type of leak sense technology to enable leak detection and notification capabilities. In certain examples, the leak sense mechanism or components may report any suitable number of errors. For example, the reported coolant leak errors may include, but are not limited to, a small leak or warning error, a large leak or critical error, and leak sensor error. The leak sensor error may be a warning that indicates an issue with the leak detection board of information handling system 110.

In an example, a baseboard management controller (BMC) of information handling system 110 may perform the leak sense operations. In response to a coolant leak detection, the BMC may perform one or more actions. For example, the BMC may provide a coolant leak indication to enable components to notify a technician about the coolant leak. Additionally, in response to the detection of the coolant leak, the BMC may perform operations to automatically power down information handling system 100. However, the flow of the coolant liquid into information handling system 110 as possibly all of server rack 102 does not end when the information handling system is powered down. Therefore, the BMC of the affected information handling system 110 may cause components of server rack 102 and console 104 to perform actions to notify technicians about the leak and the location of the leak.

As will be described herein, console 104, TOR display 114, TOR leak indicator 116, and LEDs 120 may combine to provide audiovisual messaging to indicate the severity of the coolant leak and the location of the leak. These components may provide focused and clear messaging associated with the detection of a coolant leak, and the messaging may be located at different locations within system 100. In certain examples, the locations may include, but are not limited to, ‘at-the-box’, ‘at-the-rack’, and ‘at-the-console’.

In response to the BMC of a particular information handling system 110 detecting a coolant leak, the BMC may cause LED 120 of that information handling system to illuminate. In an example, LED 120 may illuminate in any suitable color to enable a technician or anyone associated with server rack 102 to quickly and clearly identify the information handling system 110 with the detected coolant leak. For example, LED 120 may be amber or any other color not utilized by other LEDs on information handling system 110. This difference in the color of LED 120 enables an individual to quickly scan all information handling systems 110 within server rack 102 to identify the information handling system with the coolant leak.

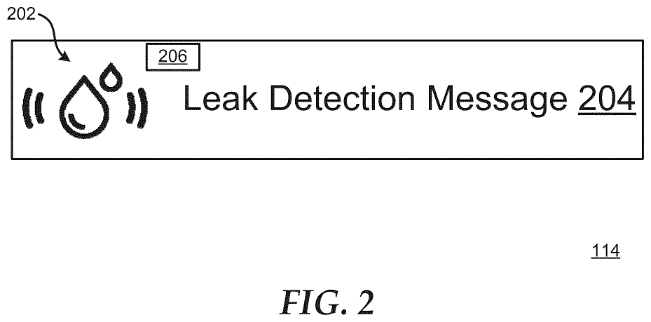

In certain examples, LED 120 may include iconography to further distinguish information handling system 110 with the detected coolant leak from all other information handling systems in server rack 102. In an example, the iconography for LED 120 may be a different shape illuminated by the LED, such as a star, a water drop, or the like. In certain examples, the water drop iconography for LED 120 may be substantially similar to leak detection icon 202 in FIG. 2. In an example, LED 120 may blink or strobe at different frequencies and the frequency may be increased based on severity of coolant leak.

While LEDs 120 provide quick identification of information handling system 110 experiencing the coolant leaking, server rack 102 may be located in a large pod or datacenter that includes multiple server racks. In this situation, an individual should first be able to identify server rack 102 as the rack with the detected coolant leak. In an example, information handling system 110 may communicate with TOR leak indicator 116 to identify server rack 102 as the server rack affected by the coolant leak. Any suitable component within information handling system 110, such as the BMC, may communicate a leak indication to TOR leak indicator 116 through communication channel 150. In certain examples, the leak indication may be provided directly from information handling system 110 to TOR leak indicator 116, the leak indication may be routed through rack management component 112, or the like.

In response to receiving the leak indication, TOR leak indicator 116 may provide focused and clear messaging about the detection of the coolant leak in server rack 102. In an example, the focused and clear messaging may be provided by the combination of visual leak indicator 140 and audio leak indicator 142. In certain examples, TOR leak indicator 116 may attach to the top of server rack 102 by any suitable manner. For example, TOR leak indicator 116 may be bolted to the top of server rack 102, may be magnetically attached to the top, or the like.

In certain examples, visual leak indicator 140 may be a beacon component that illuminates a particular color. For example, visual leak indicator 140 may be amber in color. In an example, visual leak indicator 140 may may blink or strobe at different frequencies and the frequency may be increased based on severity of coolant leak. In this example, leak indication from information handling system 110 may include data to identify the severity of the coolant leak and TOR leak indicator 116 may adjust the blinking frequency of visual indicator 140 based on the severity of the coolant leak.

In an example, audio leak indicator 142 may be a siren. In response to the leak indication, audio leak indicator 142 may sound a shrill audio alert. In certain examples, the shrill audio alert may be uniquely differentiated from the background noise of information handling systems 110 running in the datacenter. In an example, the audio alert of audio leak indicator 142 may sound at different frequencies based on the severity of the coolant leak as identified by the leak indication signal. TOR leak indicator 116 may enable a clear audiovisual indication above server rack 102 to enable an individual to quickly locate and identify the server rack as the distressed server rack within the pod or datacenter. As described herein, LEDs 120 may provide a fine location, such as information handling system 110, for the coolant leak and TOR leak indicator 116 may provide a gross location, such as server rack 102, for the coolant leak.

FIG. 2 illustrates TOR display 114 according to at least one embodiment of the present disclosure. TOR display 114 includes a leak detection icon 202, a leak detection message 204, and a LED 206. In an example, TOR display 114 may be any suitable type of display to output messages associated with the coolant leak or status of information handling systems 110 in server rack 102 of FIG. 1. For example, TOR display 114 may be an electronic-ink (e-ink) display that holds an image until a next image is programmed into the display. Operation of TOR display 114 will be described with respect to FIGS. 1 and 2. TOR display 114 may include additional components without varying from the scope of this disclosure.

In certain examples, leak detection message 204 may be any suitable alphanumeric message to provide a summary of the health status for information handling systems 110 in server rack 102. For example, if all information handling systems 110 are operating properly and no coolant leaks have been detected, message 204 may indicate a good health status for server rack 102. However, in response to the leak indication, message 204 may provide information associated with the coolant leak. For example, message 204 may indicate a particular information handling system 110 that has the coolant leak, such as “22U LEAK DETECTED!!”.

In an example, information handling system 110 may communicate with TOR display 114 to provide the leak indication. Any suitable component within information handling system 110, such as the BMC, may communicate the leak indication to TOR display 114 through communication channel 150. In certain examples, the leak indication may be provided directly from information handling system 110 to TOR display 114, the leak indication may be routed through rack management component 112, or the like.

In response to receiving the leak indication, TOR display 116 may provide leak detection icon 202. In an example, leak detection icon 202 may be any suitable design to enable an individual to easily and quickly identify a coolant leak has been detected within server rack 102. In certain examples, leak detection icon 202 may be a main water droplet. Leak detection icon 202 also may be the main water droplet with a smaller water droplet offset to the top right of the main water droplet image. Additionally, leak detection icon 202 also may be the main water droplet with the smaller water droplet offset to the top right of the main water droplet and one or more “)” and “(” shapes on each side of the main water droplet, as shown in FIG. 2.

In an example, LED 206 of TOR display 114 may illuminate based on reception of the leak indication. In certain examples, the color or frequency of LED 206 may differ based on a level or degree of the coolant leak. For example, if a flow of the coolant leak is less than a particular threshold amount, LED 206 may be a solid color. In an example, a solid color of LED 206 may indicate a low risk, such as the coolant leak may be slow and corrective action is not immediately required. In certain examples, the color of LED 206 may be amber or any other color that is easily distinguishable from other LED colors in server rack 102. If the flow is greater than another threshold amount, LED 206 may blink or flash. For example, a blinking of LED 206 may indicate that the coolant leak requires immediate attention. In an example, as the level or flow of the coolant leak increases, the frequency of the blinking in LED 206 may similarly increase.

In certain examples, message 204 may provide additional information associated with the coolant leak. For example, message 204 may provide geo-location information, failure codes, and a suggested remediation for the coolant leak. Additionally, message 204 of TOR display 114 may illustrate a time that server rack 102 lost power, major events associated with the server rack, or the like. The major events may be any suitable event including, but not limited to, the detection of a coolant leak and a node or information handling system 110 stopped responding. In an example, information associated with information handling systems 110 may be encoded and displayed in a quick-response (QR) code on TOR display 114. The QR code may enable an individual to utilize a cellular telephone or smart phone for quick capture/decode of the information handling systems 110.

In an example, TOR display 114 may be battery powered, such that the e-paper or e-ink TOR display may maintain the last image and LED 206 status without a lot of power usage. Additionally, TOR display 114 may be optimized for low power usage based on the TOR display being a zero-input/zero-button display, such that the TOR display may only provide outputs to convey the status of information handling systems 110. TOR display 114 may provide live status information for information handling systems 110, and forensic debug information based on a failure or coolant leak.

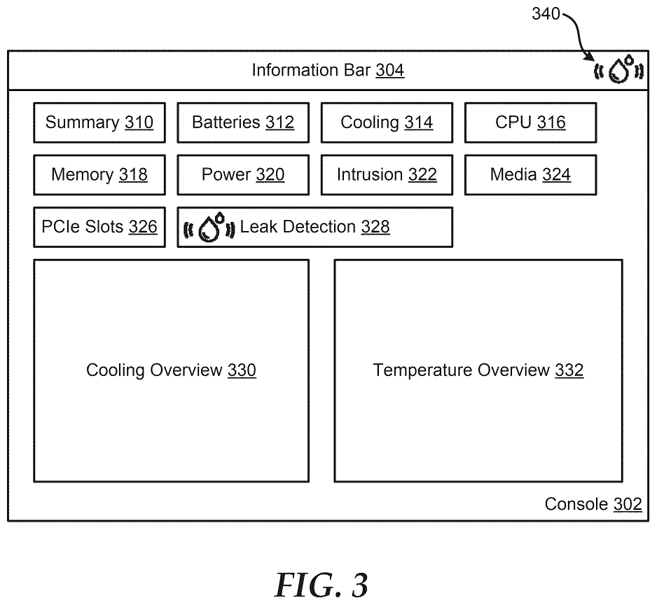

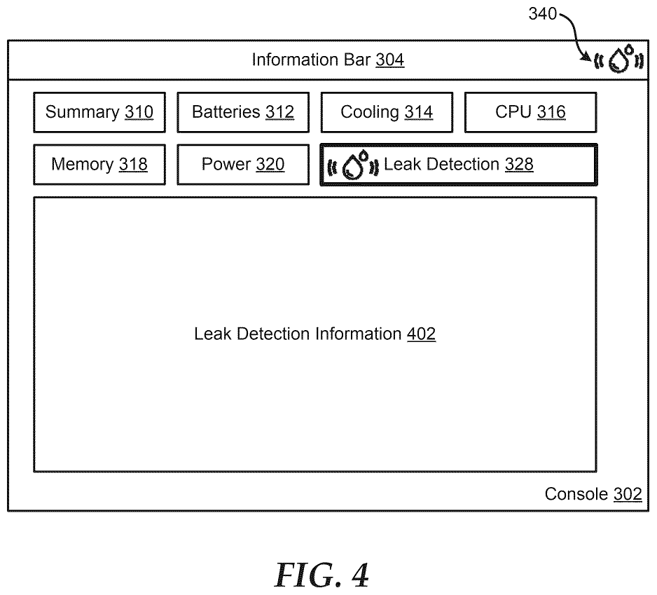

FIGS. 3 and 4 illustrate different graphical user interfaces (GUIs) on a console 302 according to at least one embodiment of the present disclosure. In an example, console 302 may be substantially similar to console 104 of FIG. 1. The GUI on console 302 includes an information bar 304 that may be utilized to identify a corresponding information handling system or BMC of the information handling system being accessed. The GUI also includes any suitable number of buttons, tiles, or tabs. For example, the GUI includes a summary button 310, a batteries button 312, a cooling button 314, a CPU button 316, a memory button 318, a power button 320, a media button 324, a PCIe slots button 326, and a leak detection button 328 (buttons 310-328). The GUI also includes overview panes 330 and 332. Leak detection button 328 may include a leak detection icon, and the image of the leak detection icon may be substantially similar to the image of leak detection icon 202 of FIG. 2. The GUI of console 302 may include additional buttons, tiles, or tabs without varying from the scope of this disclosure.

During operation of console 302, overview panes 330 and 332 may provide additional information handling associated with an information handling system, such as a cooling overview, a temperature overview, or the like. An individual may select one of the buttons 310-328 to view more information associated with the button. In an example, leak detection button 328 may be non-descript when no leak indication has been received. In this situation, leak detection button 328 may clearly indicate the healthy system, such as no leak present, when no change is made in the leak detection button.

In an example, console 302 may receive a leak indication from one of information handling systems 110, a leak detection icon 340 may be displayed on the GUI of the console. The image of leak detection icon 340 may be substantially similar to the image of leak detection icon 202 of FIG. 2. Based on leak detection icon 340 being displayed on the GUI of console 302, an individual may realize that a coolant leak has been detected in the associated information handling system. In certain examples, based on the leak indication, console 302 may provide any suitable audiovisual outputs to further identify a coolant leak in the corresponding information handling system.

In an example, the leak indication may express the urgency of the coolant leak to remote users of console 302. In certain examples, the leak indication may be received as an alert via a networked channel, such as an electronic mail (email) message, a simple network management protocol (SNMP) message, a bare metal server (BMS) message, or the like. In an example, console 302 may output an audio signal, such as a siren, a beeping, or the like, to indicate that the leak indication has been received. Additionally, in response to the leak indication, console 302 may cause leak detection button 328 to flash. In response to any or all of these audiovisual outputs, the individual may select leak detection button 328 to view more information about the coolant leak as illustrated in FIG. 4.

Referring to FIG. 4, leak detection button 328 is highlighted, indicating that this button has been selected. In response to leak detection button 328 being selected, the GUI on console 302 may display leak detection information 402. In an example, leak detection information 402 may include any suitable data associated with the coolant leak. For example, leak detection information 402 may include the identity of the information handling system having the coolant leak, a severity level of the leak, a current status of the information handling system and other information handling systems in the server rack, suggested remediations for the coolant leak, or the like.

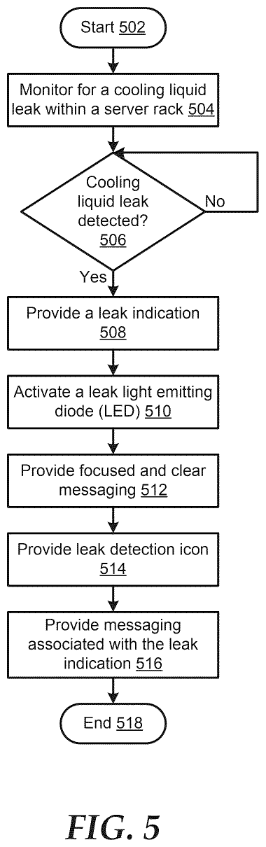

FIG. 5 shows a method 500 for providing comprehensive leak detection messaging according to at least one embodiment of the present disclosure, starting at block 502. Not every method step set forth in this flow diagram is always necessary, and certain steps of the methods may be combined, performed simultaneously, in a different order, or perhaps omitted, without varying from the scope of the disclosure. FIG. 5 may be employed in whole, or in part, a processor of information handling system 110 in FIG. 1, console 104 in FIG. 1, TOR leak indicator 116 in FIG. 1, TOR display 114 in FIG. 1, or any other type of controller, device, module, processor, or any combination thereof, operable to employ all, or portions of, the method of FIG. 5.

At block 504, monitor for a cooling liquid leak within a server rack. In certain examples, the monitoring for the cooling liquid leak may be performed in any suitable manner. For example, the monitoring may be performed by any suitable manner known in the art. At block 506, a determination is made whether a cooling liquid leak has been detected. In response to the cooling leak being detected, a leak indication is provided at block 508. In an example, the leak indication may include a coolant leak error, such as a small leak or warning error, a large leak or critical error, leak sensor error, or the like. The leak sensor error may be a warning that indicates an issue with the leak detection board of information handling system 110.

At block 510, a leak LED is activated. In an example, the LED may illuminate in any suitable color to enable a technician or anyone associated with the server rack to quickly and clearly identify the information handling system with the detected coolant leak. For example, the LED may be amber or any other color not utilized by other LEDs on the information handling system. This difference in the color of the LED may enable an individual to quickly scan all of the information handling systems within the server rack to identify the information handling system with the coolant leak.

In certain examples, the LED may include iconography to further distinguish the information handling system with the detected coolant leak from all other information handling systems in the server rack. In an example, the iconography for the LED may be a different shape illuminated by the LED, such as a star, a water drop, or the like. In certain examples, the water drop iconography for the LED may be substantially similar to a leak detection icon. In an example, the LED may blink or strobe at different frequencies and the frequency may be increased based on severity of coolant leak.

At block 512, focused and clear messaging is provided. The focused and clear messaging may be provided by a TOR leak indicator in response to reception of a leak indication. This messaging may be associated with the detection of the coolant leak in the server rack. In an example, the focused and clear messaging may be provided by the combination of a visual leak indicator and an audio leak indicator.

In certain examples, the visual leak indicator may be a beacon component that illuminates a particular color. For example, the visual leak indicator may be amber in color. In an example, the visual leak indicator may blink or strobe at different frequencies and the frequency may be increased based on severity of coolant leak. In this example, leak indication from an information handling system may include data to identify the severity of the coolant leak and the TOR leak indicator may adjust the blinking frequency of the visual indicator based on the severity of the coolant leak.

In an example, the audio leak indicator may be a siren. In response to the leak indication, the audio leak indicator may sound a shrill audio alert. In certain examples, the shrill audio alert may be uniquely differentiated from the background noise of information handling systems running in the datacenter. In an example, the audio alert of the audio leak indicator may sound at different frequencies based on the severity of the coolant leak as identified by the leak indication signal. The TOR leak indicator may enable a clear audiovisual indication above the server rack to enable an individual to quickly locate and identify the server rack as the distressed server rack within the pod or datacenter.

At block 514, a leak detection icon is provided. The leak detection icon may be provided on a TOR display. In an example, the leak detection icon may be any suitable design to enable an individual to easily and quickly identify a coolant leak has been detected within the server rack. In certain examples, the leak detection icon may be a main water droplet. The leak detection icon also may be the main water droplet with a smaller water droplet offset to the top right of the main water droplet image. Additionally, the leak detection icon also may be the main water droplet with the smaller water droplet offset to the top right of the main water droplet and one or more “)” and “(” shapes on each side of the main water droplet, as shown in FIG. 2.

At block 516, messaging associated with the leak indication is provided, and the flow ends at block 518. In certain examples, the messaging may be provided at the TOR display and at a console associated with the server rack. When the messaging is provided on the TOR display, the messaging provide information associated with the coolant leak. For example, the messaging may indicate a particular information handling system that has the coolant leak, such as “22U LEAK DETECTED!!”. The messaging on the TOR display may provide additional information associated with the coolant leak. For example, the messaging may provide geolocation information, failure codes, and a suggested remediation for the coolant leak. Additionally, the messaging on the TOR display may illustrate a time that the server rack lost power, major events associated with the server rack, or the like. The major events may be any suitable event including, but not limited to, the detection of a coolant leak and a node or information handling system stopped responding. In an example, the information associated with the information handling systems may be encoded and displayed in a QR code on the TOR display. The QR code may enable an individual to utilize a cellular telephone or smart phone for quick capture/decode of the information handling systems.

When the messaging is provided on a console, a leak detection icon may be displayed on the GUI of the console. In an example, the image of the leak detection icon may be substantially similar to the image of leak detection icon 202 of FIG. 2. Based on display of the leak detection icon on the GUI of the console, an individual may realize that a coolant leak has been detected in the associated information handling system. In certain examples, based on the leak indication, the console may provide any suitable audiovisual outputs to further identify a coolant leak in the corresponding information handling system. In an example, the console may output an audio signal, such as a siren, a beeping, or the like, to indicate that the leak indication has been received. Additionally, in response to the leak indication, the console may cause a leak detection button on the GUI of the console to flash.

FIG. 6 shows a generalized embodiment of an information handling system 600 according to an embodiment of the present disclosure. Information handling system 600 may be substantially similar to information handling system 110 of FIG. 1. Further, information handling system 600 can include processing resources for executing machine-executable code, such as a central processing unit (CPU), a programmable logic array (PLA), an embedded device such as a System-on-a-Chip (SoC), or other control logic hardware. Information handling system 600 can also include one or more computer-readable medium for storing machine-executable code, such as software or data. Additional components of information handling system 600 can include one or more storage devices that can store machine-executable code, one or more communications ports for communicating with external devices, and various input and output (I/O) devices, such as a keyboard, a mouse, and a video display. Information handling system 600 can also include one or more buses operable to transmit information between the various hardware components.

Information handling system 600 can include devices or modules that embody one or more of the devices or modules described below and operates to perform one or more of the methods described below. Information handling system 600 includes a processors 602 and 604, an input/output (I/O) interface 610, memories 620 and 625, a graphics interface 630, a basic input and output system/universal extensible firmware interface (BIOS/UEFI) module 640, a disk controller 650, a hard disk drive (HDD) 654, an optical disk drive (ODD) 656, a disk emulator 660 connected to an external solid state drive (SSD) 664, an I/O bridge 670, one or more add-on resources 674, a trusted platform module (TPM) 676, a network interface 680, a management device 690, and a power supply 695. Processors 602 and 604, I/O interface 610, memory 620, graphics interface 630, BIOS/UEFI module 640, disk controller 650, HDD 654, ODD 656, disk emulator 660, SSD 664, I/O bridge 670, add-on resources 674, TPM 676, and network interface 680 operate together to provide a host environment of information handling system 600 that operates to provide the data processing functionality of the information handling system. The host environment operates to execute machine-executable code, including platform BIOS/UEFI code, device firmware, operating system code, applications, programs, and the like, to perform the data processing tasks associated with information handling system 600.

In the host environment, processor 602 is connected to I/O interface 610 via processor interface 606, and processor 604 is connected to the I/O interface via processor interface 608. Memory 620 is connected to processor 602 via a memory interface 622. Memory 625 is connected to processor 604 via a memory interface 627. Graphics interface 630 is connected to I/O interface 610 via a graphics interface 632 and provides a video display output 636 to a video display 634. In a particular embodiment, information handling system 600 includes separate memories that are dedicated to each of processors 602 and 604 via separate memory interfaces. An example of memories 620 and 630 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 640, disk controller 650, and I/O bridge 670 are connected to I/O interface 610 via an I/O channel 612. An example of I/O channel 612 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 610 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 640 includes BIOS/UEFI code operable to detect resources within information handling system 600, to provide drivers for the resources, initialize the resources, and access the resources. BIOS/UEFI module 640 includes code that operates to detect resources within information handling system 600, to provide drivers for the resources, to initialize the resources, and to access the resources.

Disk controller 650 includes a disk interface 652 that connects the disk controller to HDD 654, to ODD 656, and to disk emulator 660. An example of disk interface 652 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 660 permits SSD 664 to be connected to information handling system 600 via an external interface 662. An example of external interface 662 includes a USB interface, an IEEE 4394 (Firewire) interface, a proprietary interface, or a combination thereof. Alternatively, solid-state drive 664 can be disposed within information handling system 600.

I/O bridge 670 includes a peripheral interface 672 that connects the I/O bridge to add-on resource 674, to TPM 676, and to network interface 680. Peripheral interface 672 can be the same type of interface as I/O channel 612 or can be a different type of interface. As such, I/O bridge 670 extends the capacity of I/O channel 612 when peripheral interface 672 and the I/O channel are of the same type, and the I/O bridge translates information from a format suitable to the I/O channel to a format suitable to the peripheral channel 672 when they are of a different type. Add-on resource 674 can include a data storage system, an additional graphics interface, a network interface card (NIC), a sound/video processing card, another add-on resource, or a combination thereof. Add-on resource 674 can be on a main circuit board, on separate circuit board or add-in card disposed within information handling system 600, a device that is external to the information handling system, or a combination thereof.

Network interface 680 represents a NIC disposed within information handling system 600, on a main circuit board of the information handling system, integrated onto another component such as I/O interface 610, in another suitable location, or a combination thereof. Network interface device 680 includes network channels 682 and 684 that provide interfaces to devices that are external to information handling system 600. In a particular embodiment, network channels 682 and 684 are of a different type than peripheral channel 672 and network interface 680 translates information from a format suitable to the peripheral channel to a format suitable to external devices. An example of network channels 682 and 684 includes InfiniBand channels, Fibre Channel channels, Gigabit Ethernet channels, proprietary channel architectures, or a combination thereof. Network channels 682 and 684 can be connected to external network resources (not illustrated). The network resource can include another information handling system, a data storage system, another network, a grid management system, another suitable resource, or a combination thereof.

Management device 690 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 600. In particular, management device 690 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 600, such as system cooling fans and power supplies. Management device 690 can include a network connection to an external management system, and the management device can communicate with the management system to report status information for information handling system 600, to receive BIOS/UEFI or system firmware updates, or to perform other task for managing and controlling the operation of information handling system 600.

Management device 690 can operate off of a separate power plane from the components of the host environment so that the management device receives power to manage information handling system 600 when the information handling system is otherwise shut down. An example of management device 690 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 690 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A server rack comprising:
an information handling system including:
a leak detection component configured to:
monitor the information handling system for a coolant leak; and
in response to a detection of the coolant leak, provide a leak indication; and
a leak light emitting diode (LED) located on a front panel of the information handling system, wherein the leak LED is activated in response to the leak indication; and
a top of rack leak indicator configured to communicate with the information handling system, in response to the leak indication, the top of rack leak indicator to provide focused and clear messaging about the detection of the coolant leak in the server rack.

2. The server rack of claim 1, wherein the leak LED provides a fine location of the coolant leak, wherein the top of rack leak indicator provides a gross location of the coolant leak.

3. The server rack of claim 1, wherein the top of rack leak indicator provides both a visual leak indicator and an audio leak indicator.

4. The server rack of claim 1, further comprising: a top of rack display to communicate with the information handling system, the top of rack display to: provide messaging associated with the detection of the coolant leak.

5. The server rack of claim 4, wherein the top of rack display to: provide a leak detection icon to indicate that the detection of the coolant leak has occurred.

6. The server rack of claim 4, wherein the top of rack display further to: provide additional information associated with the detection of the coolant leak.

7. The server rack of claim 6, wherein the additional information includes geo-location information, failure codes, and a suggested remediation.

8. The server rack of claim 4, wherein the top of rack display is an electronic ink display.

9. A method comprising:
monitoring, by a leak detection component of an information handling system, for a coolant leak within the information handling system;
in response to a detection of the coolant leak, providing, by the leak detection component, a leak indication;
in response to the leak indication, activating a leak light emitting diode (LED); and
in response to the leak indication, providing, by a top of rack leak indicator, focused and clear messaging about the detection of the coolant leak in the information handling system.

10. The method of claim 9, further comprising: providing, by the leak LED, a fine location of the coolant leak, wherein the top of rack leak indicator provides a gross location of the coolant leak.

11. The method of claim 9, further comprising: providing, by the top of rack leak indicator, both a visual leak indicator and an audio leak indicator.

12. The method of claim 9, further comprising: providing, by a top of rack display, messaging associated with the leak indication.

13. The method of claim 12, wherein the messaging indicates that the information handling system needs immediate attention.

14. The method of claim 12, further comprising: providing, by the top of rack display, additional information associated with the detection of the coolant leak.

15. The method of claim 12, further comprising: providing, by the top of rack display, a leak detection icon to indicate that the detection of the coolant leak has occurred.

16. The method of claim 12, wherein the top of rack display is an electronic ink display.

17. A system comprising:
a server rack including:
an information handling system including:
a leak detection component configured to:
monitor the information handling system for a coolant leak; and
in response to a detection of the coolant leak, provide a leak indication; and
a leak light emitting diode (LED) located on a front panel of the information handling system, wherein the leak LED is activated in response to the leak indication; and
a top of rack leak indicator configured to communicate with the information handling system, in response to the leak indication, the top of rack leak indicator to provide focused and clear messaging about the detection of the coolant leak in the server rack; and
a console to communicate with the information handling system, the console to:
provide an indication of a state of the information handling system, wherein the indication is changed from a healthy state indication to an unhealthy state indication based on reception of the leak indication.

18. The system of claim 17, wherein the server rack further includes a top of rack display to communicate with the information handling system, the top of rack display to: provide messaging associated with the detection of the coolant leak.

19. The system of claim 17, wherein the leak LED provides a fine location of the coolant leak, wherein the top of rack leak indicator provides a gross location of the coolant leak.

20. The system of claim 17, wherein the console further to: provide a leak detection icon to indicate that the detection of the coolant leak has occurred.
